(19) United States
(12) Patent Application Publication
(10) Pub. No.: US 2026/0238916 A1
(43) Pub. Date: Aug. 13, 2026

(54) ADAPTIVE DYNAMIC RANGE CONTROL

(71) Applicant: MARSHALL GROUP AB (PUBL), Stockholm (SE)

(72) Inventors: Anders Edgren, Bromma (SE); Hao Liu, Huddinge (SE); Nicolas Pignier Delafontaine, Sollentuna (SE)

(21) Appl. No.: 19/154,714

(22) PCT Filed: Feb. 5, 2024
(86) PCT No.: PCT/EP2024/052761

§ 371 Date: Aug. 7, 2025

(30) Foreign Application Priority Data
Feb. 14, 2023 (SE) 2350141-4

(51) Int. Cl. H04R 1/10; H03G 3/32; H03G 7/00; H04R 3/04

(52) U.S. Cl. CPC H04R 1/1083; H03G 3/32; H03G 7/007; H04R 3/04; H04R 2430/01; H04R 2430/03

(57) ABSTRACT

A method of controlling signal dynamics of audio data (sin) for playback by an audio playback device is presented. The method comprising receiving audio data (sin) for playback by the audio playback device and obtaining, by one or more sensor circuits (310), ambient input data (sₐ) indicative of a state of an environment of the audio playback device. The method further comprises controlling at least one DRC control parameter (115) of a dynamic range controller, DRC, (100) based on the ambient input data (sₐ), processing the audio data (sᵢₙ) by the DRC (100) to provide processed audio data (sₒᵤₜ), and providing the processed audio data (sₒᵤₜ) for playback by the audio play-back device.

### TECHNICAL FIELD

The present disclosure relates to audio processing and more precisely to control of an adaptive dynamic range controller.

### BACKGROUND

The increased availability and reduced cost of portable audio playback devices allows persons everywhere to enjoy their favourite audio. With streamed programme material, it is possible to enjoy substantially any song, podcast or audio book at any location. Such audio content is generally reproduced with high quality and the quality increases further with processing power of the audio devices. In addition, the ability to alter and customize the reproduced content increases. However, the portability and mobility comes with potential drawbacks. Audio is no longer only enjoyed in controlled environments like a living room but also in noisy environments with noise from e.g., traffic, construction etc.

In order to mitigate potentially disturbing effects of external noise, some devices are equipped with Active Noise Control.

There are shortcomings in the prior art and there is room for improvement in the processing of programme material.

### SUMMARY

It is in view of the above considerations and others that the various embodiments of this disclosure have been made. The present disclosure therefore recognizes the fact that there is a need for alternatives to (e.g. improvement of) the existing art described above. It is an object of some embodiments to solve, mitigate, alleviate, or eliminate at least some of the above or other disadvantages.

An object of the present invention is therefore to provide a new type of audio compensation which is improved over the prior art, which eliminates or at least mitigates one or more of the drawbacks discussed above. More specifically, an object of embodiments of the present invention is to provide a Dynamic Range Compensation (DRC) that is adapted based on external parameters. These objects are achieved by a technique as set forth in the appended independent claims with advantageous embodiments defined in the dependent claims related thereto.

In a first aspect, a method of controlling signal dynamics of audio data is presented. The audio data is for playback by an audio playback device. The method comprises receiving audio data for playback by the audio playback device, obtaining, by one or more sensor circuits, ambient input data indicative of a state of an environment of the audio playback device, and controlling at least one DRC control parameter of a dynamic range controller, DRC, based on the ambient input data. The method further comprises processing the audio data by the DRC to provide processed audio data, and providing the processed audio data for playback by the audio playback device.

In one variant, the method further comprises, prior to processing the audio data, filtering the audio data by means of an input filter and thereby obtaining filtered audio data. In this variant, processing the audio data further comprises processing the filtered audio data to provide the processed audio data.

In one variant, the input filter is a low-pass filter configured with a cut-off frequency within an audible frequency range.

In one variant, the cut-off frequency is below 3000 Hz

In one variant, the cut-off frequency is below 1000 Hz.

In one variant, the cut-off frequency is below 500 Hz.

In one variant, the method further comprises, prior to processing the audio data, filtering a first path of the audio data by means of an input filter thereby obtaining first filtered audio data, and filtering a second path of the audio data by means of a residual filter thereby obtaining second filtered audio data. In this variant, processing the audio data further comprises processing the first filtered audio data and combining the processed first filtered audio data with the second filtered audio data to provide the processed audio data.

In one variant, the residual filter is a high pass filter configured with a cut-off frequency within an audible frequency range.

In one variant, the cut-off frequency of the residual filter is substantially the same as the cut-off frequency of the input filter.

In one variant, at least one sensor circuit is a biometric sensing circuit configured to sense, measure or otherwise acquire ambient input data in the form of biometric data of a user of the audio playback device.

In one variant, the biometric sensing circuit is a heart-rate sensor.

In one variant, at least one sensor circuit is an accelerometer, configured to sense, measure or otherwise acquire ambient input data in the form of acceleration data indicative of an acceleration subjected to the audio playback device.

In one variant, at least one sensor circuit is an audio sensing circuit configured to sense, measure or otherwise acquire ambient input data in the form of ambient audio data indicative of ambient sound in a vicinity of the audio playback device.

In one variant, the ambient audio data comprises audio data indicative of a sound pressure level (SPL) at an Ear Reference Point (ERP) of a user of the audio playback device.

In one variant, the ambient audio data comprises audio data indicative of a background noise at the audio playback device.

In one variant, controlling the at least one DRC control parameter of the DRC comprises determining a Root Mean Square (RMS) level of the ambient input data.

In one variant, the at least one DRC control parameter is determined based on a predetermined data set mapping each of a plurality of RMS levels of ambient input data to a specific DRC control parameter.

In one variant, the at least one DRC control parameter is determined based on weighting of a first DRC control parameter and a second DRC control parameter. The first DRC control parameter is determined based on a first predetermined data set mapping each of a plurality of SPLs at an ERP of a user of the audio playback device to a specific DRC control parameter. The second DRC control parameter is determined based on a second predetermined data set mapping each of a plurality of background noise levels to a specific DRC control parameter.

In one variant, the at least one DRC control parameter is one of a compression-expansion, a gain or a threshold of the DCR.

In a second aspect, a processor circuit is presented. The processor circuit is operatively coupled to a communications circuit of an audio playback device, a transducer circuit of the audio playback device, a DRC circuit of the audio playback device, and at least one sensor circuit. The processor circuit is configured to cause reception, by the communications circuit, of audio data for sounding by the transducer circuit, obtainment, by one or more sensor circuits, ambient input data indicative of a state of an environment of the audio playback device, and controlling of a DRC control parameter of the DRC circuit based on the ambient input data. The processor circuit is further configured to cause processing of the audio data by the DRC to provide processed audio data and provisioning of the processed audio data for sounding by the transducer circuit.

In one variant, the processor circuit is further configured to cause, prior to processing the audio data, filtering of the audio data by means of an input filter and thereby causing obtaining of filtered audio data. In this variant, causing processing of the audio data further comprises causing processing of the filtered audio data to provide the processed audio data.

In one variant, the input filter is a low-pass filter configured with a cut-off frequency within an audible frequency range.

In one variant, the cut-off frequency is below 3000 Hz

In one variant, the cut-off frequency is below 1000 Hz.

In one variant, the processor circuit is further configured to cause, prior to processing the audio data, filtering of a first path of the audio data by means of an input filter thereby causing obtaining of first filtered audio data, and filtering of a second path of the audio data by means of a residual filter thereby causing obtaining of second filtered audio data. In this variant, causing processing of the audio data further comprises causing processing of the first filtered audio data and causing of combining the processed first filtered audio data with the second filtered audio data to provide the processed audio data.

In one variant, at least one sensor circuit is a biometric sensing circuit configured to sense, measure or otherwise acquire ambient input data in the form of biometric data of a user of the audio playback device.

In one variant, the biometric sensing circuit is a heart-rate sensor.

In one variant, at least one sensor circuit is an accelerometer, configured to sense, measure or otherwise acquire ambient input data in the form of acceleration data indicative of an acceleration subjected to the audio playback device.

In one variant, at least one sensor circuit is an audio sensing circuit configured to sense, measure or otherwise acquire ambient input data in the form of ambient audio data indicative of ambient sound in a vicinity of the audio playback device.

In one variant, the ambient audio data comprises audio data indicative of a sound pressure level, SPL, at an ERP of a user of the audio playback device and audio data indicative of a background noise at the audio playback device. In this variant, causing the processing of the audio data further comprises causing active noise cancelling of the background noise based on the ambient audio data.

In one variant, causing control of the at least one DRC control parameter of the DRC comprises causing determining of a Root Mean Square, RMS, level of the ambient audio data.

In one variant, the DRC control parameter is determined based on a predetermined data set mapping each of a plurality of RMS levels of ambient audio data to a specific DRC control parameter.

In one variant, the DRC control parameter is determined based on weighting of a first DRC control parameter and a second DRC control parameter. The first DRC control parameter is determined based on a first predetermined data set mapping each of a plurality of SPLs at an ERP of a user of the audio playback device to a specific DRC control parameter. The second DRC control parameter determined based on a second predetermined data set mapping each of a plurality of background noise levels to a specific DRC control parameter.

In one variant, the processor circuit is further configured to cause execution of the method according to the first aspect.

In a third aspect, an audio playback device for playback of audio data is presented. The audio playback device comprises at least one sensor circuit positioned to sense ambient input data indicative of a state of an environment of the audio playback device and a DRC circuit provided with a DRC control parameter configured based on the ambient input data. The DCR circuit is configured to process the audio data to provide processed audio data and to provide the processed audio data for playback by the audio playback device.

In one variant, at least one sensor circuit is a biometric sensing circuit configured to sense, measure or otherwise acquire ambient input data in the form of biometric data of a user of the audio playback device.

In one variant, the biometric sensing circuit is a heart-rate sensor.

In one variant, at least one sensor circuit is an accelerometer, configured to sense, measure or otherwise acquire ambient input data in the form of acceleration data indicative of an acceleration subjected to the audio playback device.

In one variant, at least one sensor circuit is an audio sensing circuit configured to sense, measure or otherwise acquire ambient input data in the form of ambient audio data indicative of ambient sound in a vicinity of the audio playback device.

In one variant, at least one audio sensor circuit is arranged to sense, detect or otherwise measure a sound pressure level, SPL, at an ERP of a user of the audio playback device and the ambient audio data comprises the sensed SPL.

In one variant, at least one audio sensor circuit is arranged to sense, detect or otherwise measure a background noise at the audio playback device wherein the ambient audio data comprises the sensed background noise.

In one variant, the audio playback device further comprises a communications circuit, a transducer circuit and a processor circuit operatively connected to the communications circuit, the transducer circuit, the audio sensor circuit and the DRC circuit. The processor circuit is configured to perform the method of the first aspect.

In one variant, the audio playback device further comprises a communications circuit, a transducer circuit and a processor circuit operatively connected to the communications circuit, the transducer circuit, the audio sensor circuit and the DRC circuit. The processor circuit is the processor circuit of the second aspect.

In a fourth aspect, a computer program product comprising a computer readable storage medium having stored thereon program instructions which, when executed on by one or more processor circuits, cause the one or more processor circuits to carry out the method according to the first aspect.

### BRIEF DESCRIPTION OF THE DRAWINGS

Embodiments of the invention will be described in the following; references being made to the appended diagrammatical drawings which illustrate non-limiting examples of how the inventive concept can be reduced into practice.

FIG. 1 is a general graph of sound pressure level versus frequency;

FIG. 2a-b are plots of probability density functions according to some embodiment of the present disclosure;

FIG. 2c is a plot of input amplitude versus output amplitude of a DRC having different compression factors according to some embodiment of the present disclosure;

FIG. 3 is a block diagram of a prior art DRC;

FIG. 4 is a block diagram of a DRC according to some embodiment of the present disclosure;

FIG. 5 is a schematic view of obtainment of DRC control parameter according to some embodiment of the present disclosure;

FIGS. 6a-d are block diagrams of different DRC circuits according to some embodiment of the present disclosure;

FIG. 7 is a schematic view of obtainment of ambient input data according to some embodiment of the present disclosure;

FIG. 8 is a block diagram of an audio playback device according to some embodiment of the present disclosure;

FIGS. 9a-c are block diagrams of audio playback devices according to some embodiment of the present disclosure;

FIG. 10 is a block diagram of a method of processing audio data according to some embodiment of the present disclosure;

FIG. 11 is a block diagram of an audio device according to some embodiment of the present disclosure;

FIG. 12 is a block diagram of a processor circuit operatively connected to an audio device according to some embodiment of the present disclosure;

FIG. 13 is a block diagram of an audio device according to some embodiment of the present disclosure;

FIG. 14 is a block diagram of a computer program and computer readable storage medium according to some embodiment of the present disclosure; and

FIG. 15 is a block diagram of a computer program loaded and a processor circuit according to some embodiment of the present disclosure.

### DETAILED DESCRIPTION OF EMBODIMENTS

Hereinafter, certain embodiments will be described more fully with reference to the accompanying drawings. The invention may, however, be embodied in many different forms and should not be construed as limited to the embodiments set forth herein; rather, these embodiments are provided by way of example so that this disclosure will be thorough and complete, and will fully convey the scope of the invention, such as it is defined in the appended claims, to those skilled in the art.

The term “coupled” is defined as connected, although not necessarily directly, and not necessarily mechanically. Similarly, the term “connected”, or “operatively connected”, is defined as connected, although not necessarily directly, and not necessarily mechanically. Two or more items that are “coupled” or “connected” may be integral with each other. The terms “a” and “an” are defined as one or more unless this disclosure explicitly requires otherwise. The terms “substantially”, “approximately” and “about” are defined as largely, but not necessarily wholly what is specified, as understood by a person of ordinary skill in the art. The terms “comprise” (and any forms thereof), “have” (and any forms thereof), “include” (and any form thereof) and “contain” (and any forms thereof) are open-ended linking verbs. As a result, a method that “comprises”, “has”, “includes” or “contains” one or more steps, possesses those one or more steps, but is not limited to possessing only those one or more steps.

Throughout the present disclosure, reference will be made to audio signals and audio data. Audio signals or audio data are, for the present disclosure, defined as encompassing any suitable content that may be processed to generate sound conceivable by humans, i.e. audio stimuli. Audio signals or audio data may be, but are not limited to, any suitable form of programme material (e.g. audio or video content comprising a full mix, a single track or a submix), voice data (e.g. a voice call, video call etc.), etc. Audio signals or audio data may be received, transmitted or processed in any suitable manner and is not limited to digital, analogue or electrical signals/data.

It is common knowledge in the acoustics discipline after H. Fletcher & W.A. Munson¹ that human binaural loudness hearing is not the same regarding sound pressure levels in the auditory band. In fact, it's only within a narrow band of about 100-1.5 kHz that may be represented with a 1:1 linear approximation using logarithm base 10, i. e. decibel (dB). This is particularly true for frequencies below 100 Hz, where a 1:1.7 ratio is a better approximation, as can be seen in e.g. ISO 226:2003. The lower sensitivity of perception of low frequency sound is usually a bottleneck within the field of electro-acoustic where a desired dynamic range may be difficult to accomplish whilst reproducing programme material. Dynamic range is the ratio between the largest and smallest values that a certain quantity can assume. For the present disclosure, dynamic range is referring to an audio signal and the certain quantity may be e.g., an amplitude, a power or any other suitable quantity of the audio signal. ¹ “Loudness, its definition, measurement and calculation”, H. Fletcher & W.A. Munson, JASA 1933

Reproducing music with enough sound pressure level (SPL) at low frequencies (commonly known as bass response), is generally associated with loudspeaker design, but may be equally challenging for e.g. headphones, earphones or other audio devices. There may be several reasons for the lack of bass response, a few will be discussed here. Whilst designing small loudspeakers, it is generally a common practice to add a DRC in the signal chain to compensate for this type of speakers inability to provide SPL at the lower frequencies.

Today, most listener use headphones, earphones or other audio devices with mobile stations whilst scurrying around as a distraction from the otherwise mundane existence. A background noise may become an issue in those cases which results in a reduced dynamic range. A poor industrial design will almost certainly have acoustic leakage, also resulting in a reduced dynamic range of the available SPL at the lower frequencies.

Some solutions to the above issues are active noise control (ANC) and automatic frequency correction. The ANC improves the dynamic range by lowering the noise floor whereas the automatic frequency correction improves it by e.g., increasing the overall signal being reproduced at the ear. Both these methods are quite elaborate and usually require some machine processing.

The utilization of ANC in an audio playback device is generally performed by obtaining a measure of an ambient noise, and injecting an inverse of the ambient noise in an audio stream that is sounded by the audio playback device. The intention is generally to reduce the ambient noise at an eardrum of a user of the audio playback device. ANC is generally configured to reduce noise at low and medium frequencies for which the various acoustic transmission paths through the audio playback device and to the eardrum do not vary significantly between users and wearing conditions.

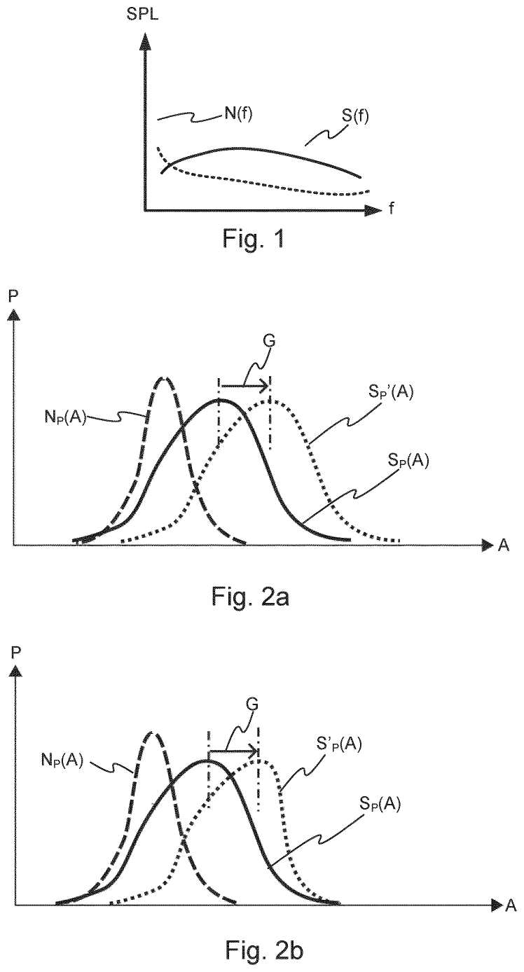

FIG. 1 shows an SPL of noise N(f) (dotted line) as a function of frequency f together with an SPL of an audio signal S(f) (solid line) as a function of frequency f. At low frequencies, an SPL of the noise N(f) is larger than or close to the audio signal S(f) which means that it will be difficult to discern the audio signal over the noise N(f). As a result, a signal to noise ratio (SNR), i.e. a ratio of an SPL of the audio signal S(f) in relation to an SPL noise of the N(f) would be low or negative for low frequencies meaning that the audio signal S(f) is masked by the noise N(f).

ANC would improve the SNR but the inventors behind the present disclosure have, through inventive thinking, realized that the SNR may be improved by different techniques. It should be mentioned already now that these techniques may very well be combined with e.g. ANC to further improve the SNR.

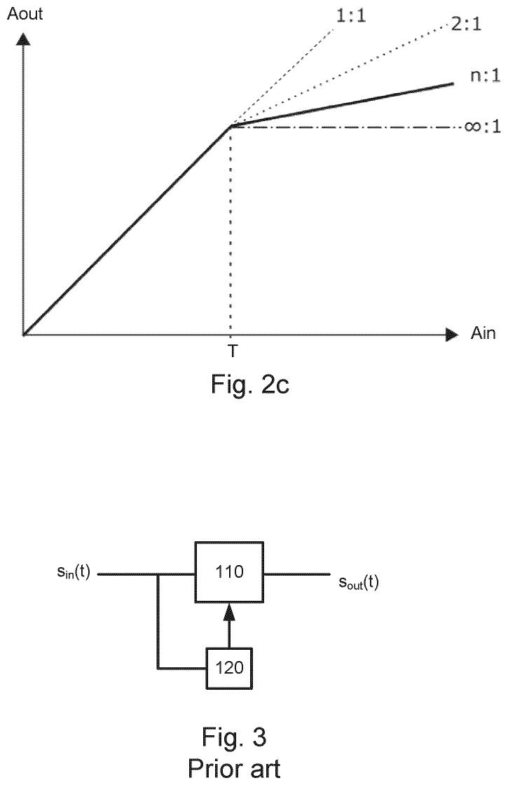

In FIG. 2a, a probability density functions of noise N_{P}(A) (dashed line) and audio signal S_{P}(A) (solid line) for different amplitudes A are shown. The probability density functions N^{P}(A), S^{P}(A) describe, as is well known in the art, a probability P that a signal will exhibit a specific amplitude A. As seen in FIG. 2a, there is a significant probability that the amplitude A of the noise N(f) and/or the audio signal S(f) will be such that the audio signal is, partly or wholly, masked by the noise signal. A blunt, but still straightforward, way to increase the SNR (in FIG. 2a, decrease a probability that the audio signal S(f) is, partly or wholly, masked by the noise signal N(f)) would be to simply apply a gain G to the audio signal S(f) effectively shifting its probability density function S^{P}(A) and thereby reducing a probability that the SNR of the audio signal S(f) and the noise N(f) is low (e.g., below a threshold) or negative. This is shown by a probability density function of an amplified audio signal S′_{P}(A) (dotted line) in FIG. 2a. This is comparable to an increase in playback volume whilst at a noisy environment to ensure that the audio signal S(f) is heard.

However, bluntly increasing the playback volume in noisy environment is not a suitable measure for increasing the SNR. There is a risk that increased playback volume will damage a hearing ability of a listener, if too high gain is applied, there is a risk of clipping and/or distortion and increasing the playback volume will increase power consumption. This will limit a usable dynamic range of an audio playback device sounding the audio signal S(f), i.e. a user may not increase the volume as much as needed in order to hear the audio above the noise N(f) without risking clipping and/or distortion of the audio signal S(f). Further, the perception of loudness will depend on the SPL and reference is made to the well-known standard ISO 226:2003 “Acoustics—Normal equal-loudness-level contours”.

In FIG. 2b, the corresponding probability density functions of noise N_{P}(A) and audio signal S_{P}(A) as in FIG. 2a is shown. In FIG. 2b, a gain G is added that shifts the audio signal probability density functions S_{P}(A) providing an amplified audio signal probability density functions Sₚ′(A) (dotted line) having a (in this example) corresponding median amplitude as provided by the amplified audio signal probability density function S_{P}′(A) shown in FIG. 2a. The difference between the amplified audio signal probability density function S_{P}′(A) of FIG. 2a and the amplified audio signal probability density functions S_{P}′(A) of FIG. 2b is that the latter exhibits substantially the same probability that a maximum amplitude is obtained as the audio signal probability density functions S_{P}(A) before the gain was added. This is accomplished by employing an amplitude dependent gain by means of a dynamic range controlled, DRC and thereby controlling the signal dynamics of the audio signal S(f). In FIG. 2b, a usable dynamic range of the audio device is increased as a user may increase the playback volume beyond that of FIG. 2a without clipping and/or distortion of the audio signal S(f).

Simply put, DRC is a signal processing operation that controls a compression-expansion factor 117 (see FIG. 5) applied to an audio signal based on a magnitude of the audio signal. Generally, a DRC is employed to control a dynamic range of an audio signal and may be utilized to e.g. avoid clipping in an audio processing chain of an audio playback device. The dynamic range may be controlled by either compression or expansion. The functionality of a general DRC is illustrated in FIG. 2c. If no DRC is active and there is a linear relation between an input amplitude Ain (or input signal level, input power) of the audio signal and the output amplitude Aout (or output signal level, output power) of the audio signal, there will be a 1:1 relation between the input amplitude Ain and the output amplitude Aout (indicated by a dashed line in FIG. 2c). It should be mentioned that the relation between the input and output signals Ain, Aout is not necessarily a 1:1 relationship but a gain applied to a low amplitude input signal is generally the same as a gain applied to a high amplitude input signal. When the DRC is active, it is generally configured to be active above or below a threshold T. The threshold T indicate an amplitude measure of the audio signal and may be in any form suitable for a specific audio signal. Audio signals having an input amplitude Ain above the threshold T will be subjected to a different gain than audio signals having an input amplitude Ain below the threshold T. This is shown in FIG. 2c by a dotted line corresponding to a compression ratio of 2:1 which means that, beyond the threshold, the output amplitude Aout will not directly reflect the input amplitude Ain. The ratio of the compression may be set arbitrarily and a solid line in FIG. 2c indicate a compression of n:1. A dash-dotted line in FIG. 2c indicate the extreme where the compression ratio is ∞:1 which means that regardless of how much the input amplitude Ain exceeds the threshold T, the same set output amplitude Aout will be provided.

Generally, a DRC is configured by monitoring, and controlling, the Root-Mean-Square RMS of a signal's amplitude.

In FIG. 2c the DRC has been shown configured to perform compression above the threshold T. It should be mentioned that the DRC may be configured to perform expansion rather than compression. If a compression-expansion factor 117 is defined as a n:m relationship, the compression will occur when n>m and expansion when n<m. Further to this, the DRC may be configured to perform compression or expansion also (or only) below the threshold T. The DRC may be configured to perform compression at one side of the threshold and expansion at the other side of the threshold. To exemplify, compression may be performed below the threshold T and/or expansion above the threshold T. The latter may sometimes be referred to as dynamic expansion as the dynamic range of the signal is effectively increased.

Throughout the present disclosure, DRC is meant to comprise any adjustment of a gain applied to an audio signal based on an input amplitude (or input signal level, input power), regardless if it decreases the dynamic range (compression) of the audio signal, increases the dynamic range (expansion) of the audio signal or leaves the dynamic range of the audio signal unaffected (combination of compression at a first portion and expansion at a second portion).

In FIG. 3, to simplify further explanation of embodiments, a schematic view of a DRC as found in the art is shown. The prior art DRC comprises a processing circuit 110 with a controllable gain that is configured to receive an audio signal sᵢₙ(t) at an input of the audio processing circuit 110 and provide a processed audio signal sₒᵤₜ(t) at the output of the audio processing circuit 110. The gain of the audio processing circuit 110 is controlled by a control circuit 120 that is configured to control the gain based on the audio signal sᵢₙ(t) at the input. The control of the gain may based on e.g. a peak detection, a root mean square (RMS), a geometric mean etc. of the audio signal sᵢₙ(t) at the input.

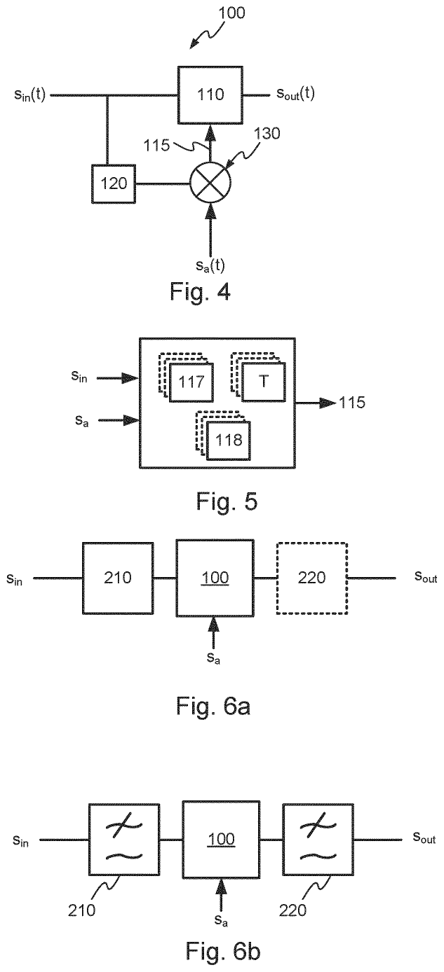

In FIG. 4 a schematic view of a DRC 100 according to embodiments of the present disclosure is shown. The DRC 100 may be referenced to as a DRC circuit 100. The DRC 100 comprises an audio processing circuit 110 that may correspond to the audio processing circuit of the prior art DRC and a control circuit 120 that may be a control circuit 120 corresponding to the control circuit 120 of the prior art DRC. The DRC 100 is further configured to receive an auxiliary signal sₐ(t). A DRC control parameter115 is provided to the audio processing circuit 110. The DRC control parameter 115 is configured to control at least one of a threshold T of the DRC 100, a compression-expansion 117 of the DRC 100 and/or a gain 118 (see FIG. 5) of the DRC 100. The DRC 100 may be controlled based on the control circuit 120, and the auxiliary signal sₐ(t). As the control circuit 120 obtains the input audio signal sᵢₙ(t), the DRC 100 may be controlled based on the input audio signal sᵢₙ(t) and the auxiliary signal sₐ(t). The audio processing circuit 110 is configured to output processed audio signal sₒᵤₜ(t) at the output of the audio processing circuit 110. The processed audio signal sₒᵤₜ(t) is processed based on the DRC control parameter 115.

In FIG. 4, the DRC 100 comprises a combiner 130 configured to combine the output from the control circuit 120 with the auxiliary signal sₐ(t). This is one example, and in some embodiments the auxiliary signal sₐ(t) is provided to the control circuit 120 and the control circuit 120 determines the DRC control parameter 115 based on the input audio signal sᵢₙ(t) and the auxiliary signal sₐ(t). Further, the combiner 130 may be a control circuit 130 configured to determine the DRC control parameter 115 based on an output from the control circuit and the auxiliary signal sₐ(t). The combiner 130 may very well be configured to perform other tasks than the combining and the combining may comprise comparing the output from the control circuit 120 with the auxiliary signal sₐ(t). In some embodiments, the combiner 130 may be comprised in the audio processing circuit 110. In some embodiments, the combiner 130 may be comprised in the control circuit 120. In some embodiments, the combiner 130 may be comprised partly in the audio processing circuit 110 and partly in the control circuit 120, i.e. the functionality of the combiner 130 may be distributed.

It should be mentioned that although the input audio signal audio signal sᵢₙ(t), the output processed audio signal sₒᵤₜ(t) and the auxiliary signal sₐ(t) may be indicated as time based signals, the DRC 100 may be a digital DRC 100. To this end, the input audio signal sᵢₙ(t) may a digital audio signal, advantageously comprising one or more digital samples. The output processed audio signal sₒᵤₜ(t) may be a digital audio signal, advantageously comprising one or more digital samples. The auxiliary signal sₐ(t) may a digital auxiliary signal, advantageously comprising one or more digital samples. For this reason, the input audio signal sᵢₙ(t) may be referred to as audio data sᵢₙ which may be either analog or digital data and the output processed audio signal sₒᵤₜ(t) may be referred to as processed audio data sₒᵤₜ which may be either analog or digital data. Correspondingly, the auxiliary signal sₐ(t) may be referred to as auxiliary data sₐ which may be either analog or digital data.

The DRC control parameter 115 may comprise a gain of the DRC 100, the gain may be either positive, negative or unity, e.g. as presented with reference to FIG. 2a or b. Alternatively, or additionally, the DRC control parameter 115 may comprise a compression-expansion factor of 117 the DRC 100, the compression-expansion factor 117 may be either positive, negative or unity, e.g. as presented with reference to FIG. 2c. Alternatively, or additionally, the DRC control parameter 115 may comprise a threshold T of the DRC 100, the threshold T, e.g. as presented with reference to FIG. 2c. As schematically shown in FIG. 5, the DRC control parameter 115 may depend on (an amplitude of) the audio data sᵢₙ and the auxiliary data sₐ. The auxiliary data sₐ is processed to determine a level of the threshold T, the gain 118 and/or compression-expansion factor 117 of the audio processing circuit 110. The amplitude of the audio data sᵢₙ and the auxiliary data sₐ may be processed to directly determine the DRC control parameter 115. That is to say, the audio data sᵢₙ and the auxiliary data sₐ may be processed to determine a level of the threshold T, the gain 118 and/or compression-expansion factor 117 of the audio processing circuit 110. In some embodiments, a lookup table is utilized to determine at least one DRC control parameter 115 based on the auxiliary data sₐ.

The auxiliary data sₐ will be further detailed throughout the present disclosure, but as an introduction, the auxiliary data sₐ may be any suitable data describing conditions that affect an audio environment. For instance, the auxiliary data sₐ may describe a background noise such that the DRC control parameter 115 of the DRC may be adjusted to compensate for this. Additionally, or alternatively, the auxiliary data sₐ may describe biometric data of a user of the audio playback device such that that the DRC control parameter 115 of the DRC may be adjusted to compensate for e.g. throbbing pulse (heart-rate) of the user.

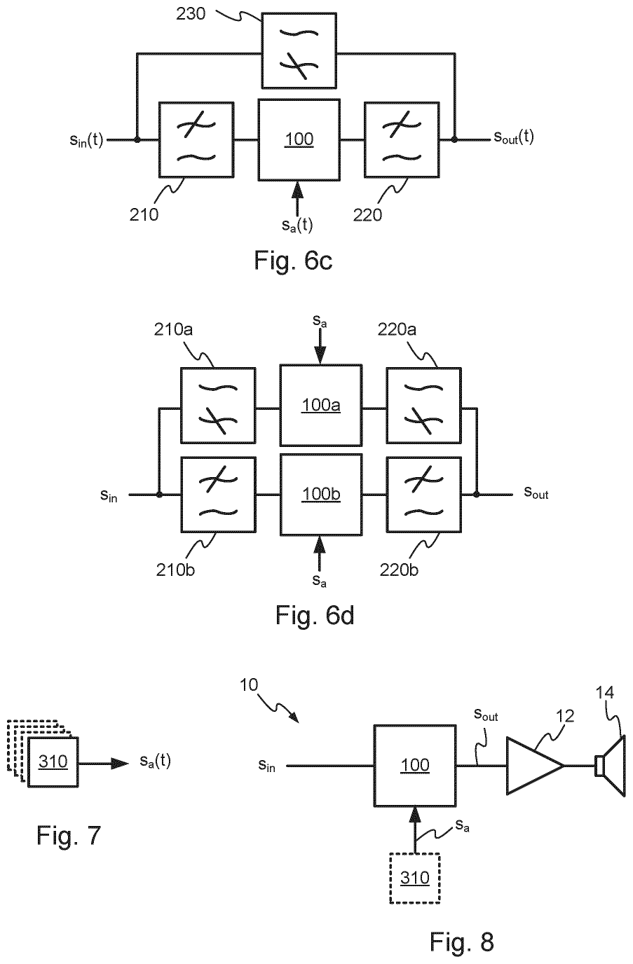

In order to limit a bandwidth of the DRC 100, the audio data sᵢₙ may be filtered prior to being processed by the DRC 100. This is illustrated in FIG. 6a by a generic input filter 210 being provided at an input of the DRC 100. The audio data sᵢₙ is provided to the input filter 210 such that filtered audio data is output from the input filter 210 and provided at the input of the DRC 100 to provide the processed audio data sₒᵤₜ. In order to e.g. filter unwanted artefacts resulting from the processing of the DRC 100, a generic output filter 220 may be provided at the output of the DRC 100.

In FIG. 6b an advantageous embodiment is illustrated wherein the input filter 210 is a low pass filter. This embodiment may be referred to as a low-pass DRC 100. In this embodiment, also the output filter 220 is a low pass filter and advantageously, the output filter 220 is substantially equivalent to the input filter 210 with regards to a frequency response of the filter 210, 220. Advantageously, the low-pass filter(s) 210, 220 are configured with a cut-off frequency within an audible frequency range. In some embodiments, the cut-off frequency of the filter(s) 210, 220 is below 3000 Hz. In an advantageous embodiment, the cut-off frequency of the filter(s) 210, 220 is below 1000 Hz. In a further advantageous embodiment, the cut-off frequency of the filter(s) 210, 220 is below 500 Hz.

In some embodiments, see FIG. 6c, in order not to lose any frequency content of the audio signal, the audio data sᵢₙ may be split into one path that feeds the input filter 210 such that filtered audio data is output from the input filter and provided at the input of the DRC 100. Another path carries the audio data sᵢₙ through a residual filter 230. The two paths are combined at the output of the DRC 100 to provide the processed audio data sₒᵤₜ. In this example, the path comprising the DRC 100 is corresponding to the embodiment of FIG. 6b. The residual filter 230 is advantageously complementary to the input filter 210 and/or the output filter 230. This is beneficial as the processed audio data provided from the DRC 100 is not combined with unfiltered audio data sᵢₙ which may reduce an effect of the processing provided by the DRC 100.

In FIG. 6d, one embodiment is shown wherein both paths are provided with a separate DRC 100a, 100b. A first DRC 100a is a high-pass DRC which means that it is arranged between a first input filter 210a being a high-pass filter and a first output filter 220a also being a high-pass filter. A second DRC 100b is a low-pass DRC 100 which means that it is arranged between a second input filter 210a being a low-pass filter and a second output filter 220a also being a low-pass filter. The high-pass DRC 100a and the low-pass DRC 100b may be configured differently such that their respective combiners 130 (not shown in FIG. 6d) combine/weight/process the input data Sin and the auxiliary data Sa are configured based on their respective operation band (i.e. frequency range in which they operate).

From FIGS. 6a-d it is clear that a number of different arrangements may be provided by filtering the input data sᵢₙ. Although not show, it should be clear that also embodiments with more than two paths are well within the scope of the present disclosure. Some or all of these paths may be provided with a DRC 100, and some or all of these paths may be provided with input filters 210 and optionally output filters 220. As the skilled person will appreciate, in some embodiments it may be advisable to configure one or more filters 210, 220 as band-pass filters.

As previously mentioned, the auxiliary data sₐ may be any suitable data describing conditions that affect an audio environment. The auxiliary data Sa may be obtained from external sources, i.e. sources external to a device housing the DRC 100. To exemplify, the auxiliary data sₐ may be obtained from a portable electronic device, e.g. a mobile phone, configured to wirelessly stream audio to an audio playback device in the form of a pair of headphones. In this example, the DRC 100 is comprised in the headphones. A common DRC 100 may be employed for both headphones or each headphone may employ a respective DRC 100. The latter is advantageous if, for instance, the pair of headphones are wireless headphones and specifically if the headphones are true wireless stereo (TWS) earphones. The auxiliary data sₐ may be obtained from the portable electronic device. The portable electronic device may in turn be configured to obtain the auxiliary data sₐ from one or more remote servers or services such as a configuration server or weather service.

Advantageously, the auxiliary data sₐ is ambient input data sₐ. That is to say, the auxiliary data sₐ is data relating to an ambient environment of the audio playback device. In an advantageous embodiment, the auxiliary data sₐ, i.e. the ambient input data sₐ is obtained from one or more sensor circuits 310, see FIG. 7. The sensor circuits 310 may be arranged at the audio playback device, or at, or operatively connected to, a device connected to the playback device, e.g. the portable electronic equipment of the previous example.

In FIG. 8, a block diagram of an audio playback device 10 according to some embodiments is shown. The audio playback device 10 comprises a DRC 100 that may be any DRC 100 embodied or exemplified in the present disclosure. The DRC 100 is configured to receive audio data sᵢₙ and output processed audio data sₒᵤₜ by processing the audio data sᵢₙ based on an amplitude (power, signal strength etc.) of the audio data sᵢₙ and the ambient input data sₐ. The ambient input data sₐ is obtained from one or more sensor circuits 310. Some of the sensor circuits may be comprised in the audio playback device 10 and other may be operatively connected to the audio playback device 10. The processed output audio data sₒᵤₜ is advantageously provided to an audio amplifier circuit 12 which is configured to amplify (or attenuate) the output audio data sₒᵤₜ and provide it to a speaker element 14 (transducer circuit) of the audio playback device 10. In some embodiments, the audio amplifier circuit 12, or a any other suitable amplification circuit may be comprised in the DRC 100 and arranged at the output of the audio processing circuit 110. This amplification circuit may be configured to provide post DRC gain adjustments to control an amplitude of the processed output audio data sₒᵤₜ.

The block diagram of the audio playback device 10 shown in FIG. 8, and any other illustrations of audio playback devices 10 for that matter, are simplified schematic views. Some circuitry may be omitted, such as a digital to analogue (DA) converter, filters 210, 220 etc. The skilled person will know what circuitry that is omitted and will have no problems understanding or implementing the teaching presented herein despite any circuitry lacking.

In the following, a few embodiments of different sensor circuits 310 suitable for providing the auxiliary data sₐ will be discussed. In the present disclosure, a sensor is to mean any device, circuit, arrangement etc. configured to sense, measure or otherwise acquire ambient input data sₐ. These following embodiments are exemplary and should not be considered exhaustive. Further, the different embodiments may be freely combined with each other without loss of functionality or effect.

In some embodiments, at least one sensor circuits 310 is a biometric sensor circuit. The biometric sensor is advantageously arranged at the audio playback device but may. In some embodiments, the biometric sensor is a separate device or arrangement operatively connected to the audio playback device or the portable electronic equipment. The biometric sensor is configured to sense, measure or otherwise acquire biometric data associated with a user of the audio playback device. In some embodiments, the biometric sensor is a sensor configured to sense, measure or otherwise acquire a blood oxidation of the user of the audio playback equipment. In an advantageous embodiment, the biometric sensor is a sensor arranged and configured to sense, measure or otherwise acquire a heart-rate (pulse) of the user of the audio playback equipment. The user's heart-rate may be an indicator of how physically active the user currently is. If the user's physical activity is increasing, i.e. the user's heart-rate is accelerating, the user may be able to hear his/her own pulse which reduces a perceived SNR of played audio. Generally, the throbbing/whizzing of the pulse is a low frequency sound. Consequently, if the ambient input data sₐ indicate an increase in pulse, the DRC 100, advantageously a low-pass DRC 100, may be configured to control the DRC control parameter 115 to increase a gain at low amplitude audio data sᵢₙ in order to ensure that weak sounds are not drowned by the pulse.

Alternatively, or additionally, in some embodiments, at least one sensor circuit 310 be a sensor circuit configured to sense, measure or otherwise acquire ambient input data sₐ in the form of acceleration data indicative of an acceleration subjected to the audio playback device 10. A suitable sensor circuit for such a task may be an accelerometer circuit. Analogues to the heart-rate sensor, the acceleration data may be a measure of a physical activity of the user of the audio playback device 10. If the acceleration data indicate that the audio playback device 10 is at rest, it is likely that the environment is tranquil with low risk of disturbances. In such an environment it may be suitable to configured the DRC for expansion by, for instance configuring the DRC 100 to control the DRC control parameter 115 to decrease a gain at low amplitude audio data sᵢₙ and/or to increase a gain at high amplitude audio data sᵢₙ. Further, if the auxiliary data sₐ indicate an increase in acceleration, the DRC 100 may be configured to control the DRC control parameter 115 to increase a gain at low amplitude audio data sᵢₙ.

Additionally, or alternatively, in some embodiments, at least one sensor circuit 310 is an audio sensing circuit configured to sense, measure or otherwise acquire ambient input data sₐ in the form of ambient audio data. The ambient audio data is indicative of ambient sound in a vicinity of the audio playback device 10. The audio sensing circuit may be a microphone. The audio sensing circuit is advantageously arranged to detect a noise ambient to the audio playback device 10. That is to say, if the ambient input data sₐ indicate an increase in noise, or a noise above a noise threshold, the DRC 100, advantageously a low-pass DRC 100, may be configured to control the DRC control parameter 115 to increase a gain at low amplitude audio data sᵢₙ in order to ensure that weak sounds are not masked by the noise.

In some further embodiments, one or more audio sensing circuit may be a feed forward microphone of the audio playback device 10. The feed forward microphone is generally located, arranged and/or configured to detect sounds outside the audio playback device 10, i.e. outside an acoustic cavity formed between the speaker element 14 and an eardrum of the user. In such embodiments, the ambient audio data sₐ comprises audio data indicative of a background noise at the audio playback device 10. If the playback arrangement 10 is a pair of closed on-ear headphones, the feed forward microphone is located, arranged and/or configured to detect sounds outside the closed volume formed between the closed on-ear headphones and a head of the user. It is common for audio playback devices with active noise cancellation (ANC) to comprise a feed forward microphone which allows a DRC 100 according to the present disclosure to obtain ambient input data sₐ from a feed forward microphone without any additional hardware.

In some further embodiments, one or more audio sensing circuit may be a feedback microphone of the audio playback device 10. The feedback microphone is generally located, arranged and/or configured to detect sounds inside the audio playback device 10, i.e. inside the acoustic cavity formed between the speaker element 14 and an eardrum of the user. In such embodiments, the ambient audio data sₐ comprises audio data indicative of an SPL at an Ear Reference Point (ERP) of the user of the audio playback device 10. If the playback arrangement 10 is a pair of closed on-ear headphones, the feedback microphone is located, arranged and/or configured to detect sounds inside the closed volume formed between the closed on-ear headphones and a head of the user. It is common for audio playback devices with active noise cancellation (ANC) to comprise a feedback microphone which allows a DRC 100 according to the present disclosure to obtain ambient input data sₐ from a feedback microphone without any additional hardware.

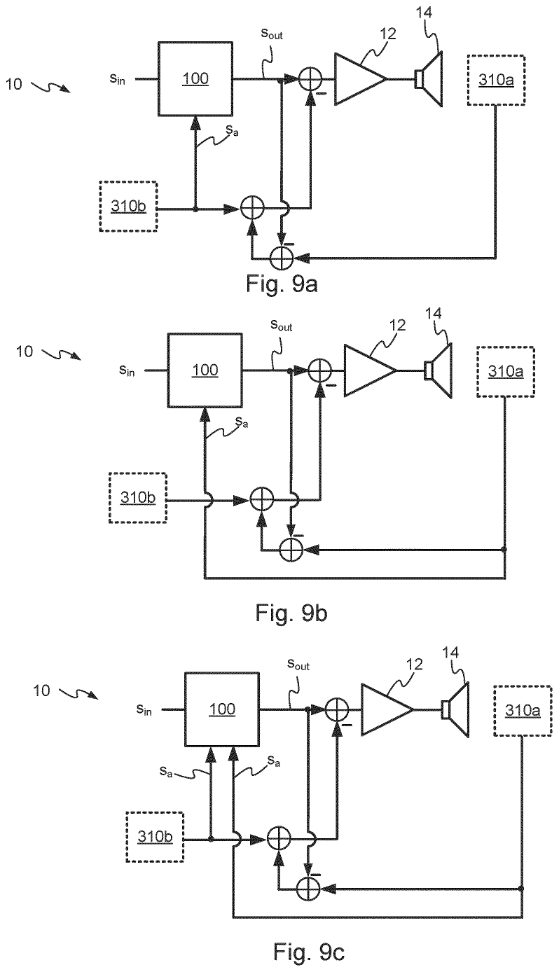

With reference to FIGS. 9a-c some non-limited specific embodiments of how the ambient input data Sa may be obtained in embodiments of audio speaker arrangements 10 comprising a first audio sensing circuit 310a comprising a feedback microphone 310a and a second audio sensing circuit 310b comprising a feed forward microphone 310b. In these embodiments, the audio playback device is configured to perform ANC based on data from the feedback microphone 310a and the feed forward microphone 310a. To this end, the processed audio data sₒᵤₜ is removed from audio data provided by the feedback microphone 310a. The resulting audio data describe a residual noise at the feedback microphone 310a. The audio data obtained by the feed forward microphone is added to the residual noise and subtracted (generally inverted) from the processed audio data sₒᵤₜ before it is provided to the amplifier 12 and the speaker element 14. The ANC functionality is common in FIGS. 9a-c. The above description of ANC is general and simplified, the skilled person is well aware of how ANC is best implanted in an audio speaker arrangement.

In FIG. 9a, the ambient input data sₐ is obtained from the feed forward microphone 310b as previously disclosed.

In FIG. 9b, the ambient input data sₐ is obtained from the feedback microphone 310a as previously disclosed.

In FIG. 9c, the ambient input data sₐ is obtained both from the feedback microphone 310a and the feed forward microphone 310b. In this embodiment, the DRC 100 is advantageously configured to determine the DRC control parameter 115 based on a combination of the ambient input data sₐ from the feedback microphone 310a and the ambient input data sₐ from the feed forward microphone 310b. The combination ambient input data sₐ may be performed by weighting the different ambient input data sₐ, and or utilization of a look-up table linking the ambient input data sₐ to a DRC control parameter 115.

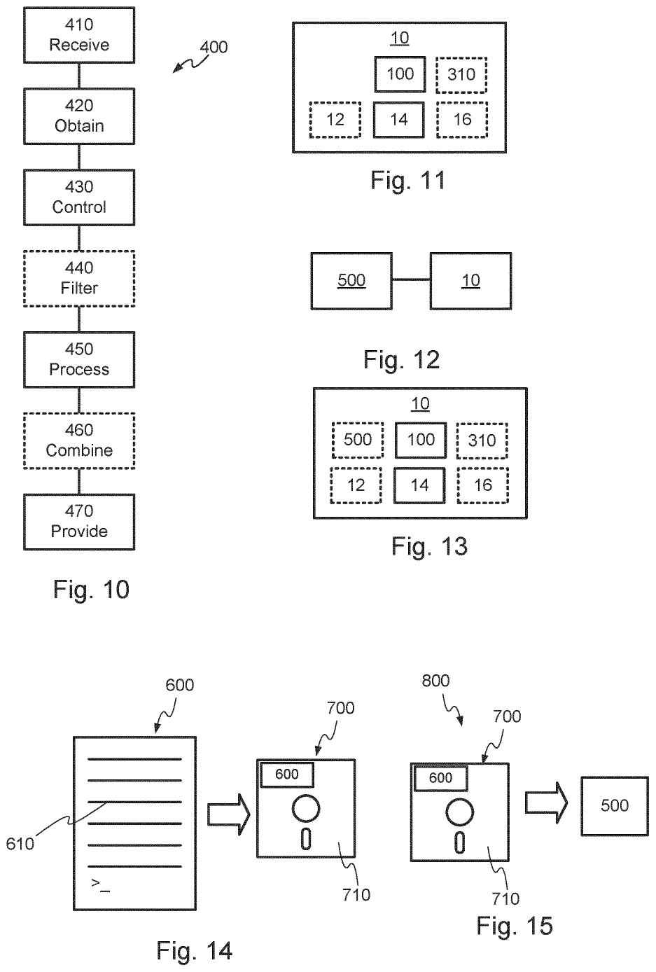

With reference to FIG. 10, a method 400 of controlling dynamics of audio data sᵢₙ for playback by an audio playback device 10 will be described. The method 400 may be expanded, modified or reduced such that it comprises providing any features presented herein in reference to any embodiment or example. The features of the method 400 are described in the order shown in FIG. 10 but may be executed in any suitable order. Some of the features may be performed in parallel to reduce execution time. The method 400 comprises receiving 410 audio data sᵢₙ. The audio data sᵢₙ may be any audio data sᵢₙ suitable for playback by the audio playback device 10. The audio data sᵢₙ may be any audio data sᵢₙ mentioned herein.

The method 400 further comprises obtaining 420 ambient input data sₐ. The ambient input data sₐ may be any ambient input data sₐ mentioned herein. Advantageously, the ambient input data sₐ is, as exemplified, obtained by one or more sensor circuits 310. The sensor circuit 310 may be a sensor circuit 310 according to any embodiment or example presented herein. The ambient input data sₐ is indicative of a state of an environment of the audio playback device 10. That is to say, the ambient input data sₐ is indicative of metrics relating to the surroundings of the audio playback device 10.

The method 400 further comprises controlling 430 the DRC control parameter 115 of the DRC 100 based on the ambient input data sₐ. The DRC may be any DRC as presented herein, and the DRC control parameter 115 may be controlled and/or determined by any means presented herein.

The method 400 further comprises processing 450 of the audio data sᵢₙ by the DRC 100. The processing 450 provides the processed audio data sₒᵤₜ according to any embodiment or example presented herein.

In some embodiments, the method may comprise filtering 440 of the audio data sᵢₙ before it is processed 450 by the DRC 100. The filtering may provide filtered and unfiltered audio data as presented herein. It may further be advantageous to perform combining 460 of the filtered and the unfiltered audio data.

The method 400 further comprises providing 470 the processed audio data sₒᵤₜ for playback by the audio playback device 10.

In FIG. 11, a block diagram of an audio playback device 10 is shown. The audio playback device 10 may comprise any suitable feature presented herein. The audio playback device 10 advantageously comprises the transducer circuit 14, i.e. the speaker element 14 and the DRC 100. In some embodiments, the audio playback device 10 may comprise the amplifier 12 and/or one or more sensor circuits 310. In some embodiments, the audio playback device 10 comprises a communications circuit 16. The communications circuit 16 may be configured for wired and/or wireless communication of audio data sᵢₙ, ambient input data sₐ, and/or control data.

In FIG. 12, a processor circuit 500 is shown. The processor circuit 500 may be any suitable processing circuit comprising one or more processors and/or controllers. The processor circuit may be configured to cause performance of configured to perform at least parts of the method 400 presented with reference to FIG. 10. To this end, the processor is advantageously operatively connected to the audio playback device 10 and suitable circuits, features and components of the audio playback device 10.

In some embodiments, see FIG. 13, the audio playback device 10 comprises the processor circuit 500.

In FIG. 14, a computer program 600 is schematically shown. The computer program 600 comprises program instructions 610 that, when run by a processor circuit 500 cause the processor circuit 500 to execute some or parts of the method 400 as presented with reference to FIG. 10. It should be mentioned that the computer program 600 and the program instructions 610 may very well be configured to cause execution of any feature or task presented herein. The computer program may 600 be stored upon, loaded onto, a computer readable storage medium 710 to form a computer program product 700. The computer readable storage medium 710 is preferably a non-volatile computer readable storage medium 710 such as, but not limited to, a flash memory, a CD-R, a floppy drive etc.

Modifications and other variants of the described embodiments will come to mind to one skilled in the art having benefit of the teachings presented in the foregoing description and associated drawings. Therefore, it is to be understood that the embodiments are not limited to the specific example embodiments described in this disclosure and that modifications and other variants are intended to be included within the scope of this disclosure. For example, while embodiments of the invention have been described with reference audio playback devices 10 in the form of headphones and earphones, persons skilled in the art will appreciate that the embodiments of the invention can equivalently be applied to other audio playback devices such as wireless speakers, home stereo systems, television sets, public broadcast systems, cinema sound systems etc. Furthermore, although specific terms may be employed herein, they are used in a generic and descriptive sense only and not for purposes of limitation. Therefore, a person skilled in the art would recognize numerous variations to the described embodiments that would still fall within the scope of the appended claims. Furthermore, although individual features may be included in different claims (or embodiments), these may possibly advantageously be combined, and the inclusion of different claims (or embodiments) does not imply that a combination of features is not feasible and/or advantageous. In addition, singular references do not exclude a plurality. Finally, reference signs in the claims are provided merely as a clarifying example and should not be construed as limiting the scope of the claims in any way.

1. A method of controlling signal dynamics of audio data for playback by an audio playback device, the method comprising:
receiving audio data for playback by the audio playback device;
obtaining, by one or more sensor circuits, ambient input data indicative of a state of an environment of the audio playback device;
controlling at least one DRC control parameter of a dynamic range controller based on the ambient input data;
processing the audio data by the DRC to provide processed audio data; and
providing the processed audio data for playback by the audio playback device.

2.-23. (canceled)

24. The method of claim 1, further comprising, prior to processing the audio data, filtering the audio data by an input filter thereby obtaining filtered audio data, wherein processing the audio data comprises processing the filtered audio data to provide the processed audio data, wherein the input filter is a low-pass filter configured with a cut-off frequency within an audible frequency range, the cut-off frequency being below 3000 Hz.

25. The method of claim 24, further comprising, prior to processing the audio data, filtering a first path of the audio data by the input filter thereby obtaining first filtered audio data, and filtering a second path of the audio data by a residual filter thereby obtaining second filtered audio data, wherein processing the audio data comprises processing the first filtered audio data and combining the processed first filtered audio data with the second filtered audio data to provide the processed audio data.

26. The method of claim 25, wherein the residual filter is a high pass filter configured with a cut-off frequency within an audible frequency range, wherein the cut-off frequency of the residual filter is substantially the same as the cut-off frequency of the input filter.

27. The method of claim 1, wherein at least one sensor circuit is a biometric sensing circuit configured to sense, measure or acquire ambient input data in the form of biometric data of a user of the audio playback device, wherein the biometric sensing circuit is a heart-rate sensor.

28. The method of claim 1, wherein at least one sensor circuit is an accelerometer, configured to sense, measure or acquire ambient input data in the form of acceleration data indicative of an acceleration of the audio playback device.

29. The method of claim 1, wherein at least one sensor circuit is an audio sensing circuit configured to sense, measure or acquire ambient input data in the form of ambient audio data indicative of ambient sound in a vicinity of the audio playback device.

30. The method of claim 29, wherein the ambient audio data comprises audio data indicative of a sound pressure level (SPL) at an Ear Reference Point (ERP) of a user of the audio playback device.

31. The method of claim 29, wherein the ambient audio data comprises audio data indicative of a background noise at the audio playback device.

32. The method of claim 1, wherein controlling the at least one DRC control parameter of the DRC comprises determining a Root Mean Square (RMS) level of the ambient input data.

33. The method of claim 32, wherein the at least one DRC control parameter is determined based on a predetermined data set mapping each of a plurality of RMS levels of ambient input data to a specific DRC control parameter.

34. The method of claim 33, wherein at least one sensor circuit is an audio sensing circuit configured to sense, measure or acquire ambient input data in the form of ambient audio data indicative of ambient sound in a vicinity of the audio playback device, wherein the ambient audio data comprises audio data indicative of a sound pressure level (SPL) at an Ear Reference Point (ERP) of a user of the audio playback device, and wherein the at least one DRC control parameter is determined based on weighting of:
a first DRC control parameter determined based on a first predetermined data set mapping each of a plurality of SPLs at an ERP of a user of the audio playback device to a specific DRC control parameter, and
a second DRC control parameter determined based on a second predetermined data set mapping each of a plurality of background noise levels to a specific DRC control parameter.

35. The method of claim 1, wherein the at least one DRC control parameter is one of a compression-expansion, a gain or a threshold of the DRC.

36. A processor circuit, operatively coupled to:
a communications circuit of an audio playback device;
a transducer circuit of the audio playback device;
a DRC circuit of the audio playback device; and
at least one sensor circuit;
wherein the processor circuit is configured to cause:
reception, by the communications circuit, of audio data for sounding by the transducer circuit;
obtainment, by one or more sensor circuits; ambient input data indicative of a state of an environment of the audio playback device;
controlling of a DRC control parameter of the DRC circuit based on the ambient input data;
processing of the audio data by the DRC to provide processed audio data; and
provisioning of the processed audio data for sounding by the transducer circuit.

37. The processor circuit of claim 36, further configured to, prior to processing the audio data, filter the audio data by an input filter thereby obtaining filtered audio data, wherein processing the audio data comprises processing the filtered audio data to provide the processed audio data, wherein the input filter is a low-pass filter configured with a cut-off frequency within an audible frequency range, the cut-off frequency being below 3000 Hz.

38. An audio playback device for playback of audio data, the audio playback device comprising:
at least one sensor circuit positioned to sense ambient input data indicative of a state of an environment of the audio playback device; and
a dynamic range controller (DRC) circuit provided with a DRC control parameter configured based on the ambient input data,
wherein the DRC circuit is configured to process the audio data to provide processed audio data and to provide the processed audio data for playback by the audio playback device.

39. The audio playback device of claim 38, wherein at least one sensor circuit is a biometric sensing circuit configured to sense, measure or acquire ambient input data in the form of biometric data of a user of the audio playback device, wherein the biometric sensing circuit is a heart-rate sensor.

40. The audio playback device of claim 38, wherein at least one sensor circuit is an accelerometer, configured to sense, measure or acquire ambient input data in the form of acceleration data indicative of an acceleration of the audio playback device.

41. The audio playback device of claim 38, wherein at least one sensor circuit is an audio sensing circuit configured to sense, measure or acquire ambient input data in the form of ambient audio data indicative of ambient sound in a vicinity of the audio playback device.

42. The audio playback device of claim 41, wherein at least one audio sensor circuit is arranged to sense, detect or measure a sound pressure level (SPL) at an Ear Reference Point (ERP) of a user of the audio playback device and the ambient audio data comprises the sensed SPL.

43. The audio playback device of claim 41, wherein at least one audio sensor circuit is arranged to sense, detect or measure a background noise at the audio playback device, and wherein the ambient audio data comprises the sensed background noise.

44. The audio playback device of claim 38, further comprising a communications circuit, a transducer circuit and a processor circuit, the processor circuit operatively connected to the communications circuit, the transducer circuit, the audio sensor circuit and the DRC circuit, wherein the processor circuit is configured to:
receive audio data for playback by the audio playback device,
obtain, by one or more sensor circuits, ambient input data indicative of a state of an environment of the audio playback device,
control at least one DRC control parameter of a dynamic range controller (DRC) based on the ambient input data,
process the audio data by the DRC to provide processed audio data, and
provide the processed audio data for playback by the audio playback device.

45. A computer program product comprising a computer readable storage medium having stored thereon program instructions which, when executed on by one or more processor circuits, cause the one or more processor circuits to:
receive audio data for playback by the audio playback device,
obtain, by one or more sensor circuits, ambient input data indicative of a state of an environment of the audio playback device,
control at least one DRC control parameter of a dynamic range controller (DRC) based on the ambient input data,
process the audio data by the DRC to provide processed audio data, and
provide the processed audio data for playback by the audio playback device.
